(19) United States
(12) Patent Application Publication
(10) Pub. No.: US 2025/0364292 A1
(43) Pub. Date: Nov. 27, 2025

(54) METHOD FOR DELIVERING WAFER SUBSTRATE

(71) Applicant: TAIWAN SEMICONDUCTOR MANUFACTURING COMPANY LTD., HSINCHU (TW)

(72) Inventors: YU KAI CHEN, KAOHSIUNG CITY (TW); PO-HUNG CHEN, KAOHSIUNG CITY (TW)

(21) Appl. No.: 18/670,756

(22) Filed: May 22, 2024

(51) Int. Cl. H01L 21/677; H01L 21/673; H01L 21/68

(52) U.S. Cl. CPC H01L 21/67745; H01L 21/6732; H01L 21/67742; H01L 21/68

(57) ABSTRACT

A method of a wafer substrate in semiconductor manufacturing is provided. The method includes moving, by a delivery assembly, the substrate toward a mount. The delivery assembly comprising a blade, and the substrate is positioned on the blade. The method also includes detecting, by a sensor, a height of the substrate relative to the mount while the movement of the substrate. When the height of the substrate is less than a first lower threshold, the method includes terminating the movement of the substrate. When the height of the substrate is greater than the first threshold but less than a first preset value, the method includes keep moving the substrate and performing a first adjustment to adjust the position of the blade according to the height of the substrate.

### BACKGROUND

Semiconductor devices are used in a variety of electronic applications, such as personal computers, cell phones, digital cameras, and other electronic equipment. In the manufacture of integrated circuits, semiconductor substrates may be loaded into various reaction and other processing chambers using automated equipment for processing. Typically, the automated equipment includes a robot or robotic arm that may transfer a wafer (e.g., semiconductor substrate or semiconductor workpiece), from a wafer pod that holds wafers through a transfer chamber and into one or more processing chambers disposed in connection to the transfer chamber.

Despite advancements in robotic technology, there remains a need for improved systems and methods that can accurately deliver substrates while effectively preventing collisions in the highly controlled semiconductor manufacturing environment. Such improvements would enhance manufacturing efficiency and reduce the risk of damage to delicate and costly semiconductor materials.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a schematic view diagram illustrating a semiconductor substrate processing system, in accordance with some embodiments of the present disclosure.

FIG. 2 is a flow chart illustrating a method for delivery a substrate, in accordance with various aspects of one or more embodiments of the present disclosure.

FIG. 3 is a schematic view diagram illustrating a chamber while a delivery module transporting a substrate therein, in accordance with some embodiments of the present disclosure.

FIGS. 4-8 are schematic view diagrams illustrating stages of a method for delivery a substrate, in accordance with one or more embodiments of the present disclosure.

FIG. 9 is a schematic view diagram illustrating a chamber while a delivery module transporting a substrate therein, in accordance with some embodiments of the present disclosure.

FIGS. 10-14 are schematic view diagrams illustrating stages of a method for delivery a substrate, in accordance with one or more embodiments of the present disclosure.

FIG. 15 is a block diagram of various functional modules of a semiconductor substrate processing system, in accordance with one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

The present disclosure is related to the field of a brush for robotic automation within semiconductor manufacturing. More particularly, the present disclosure is related to the field of precise delivery of substrates using a robot arm to prevent wafer collision during the delivery process. In addition, the present disclosure addresses the problem of wafer warpage by detecting a 3D profile of the wafer substrate during its delivery.

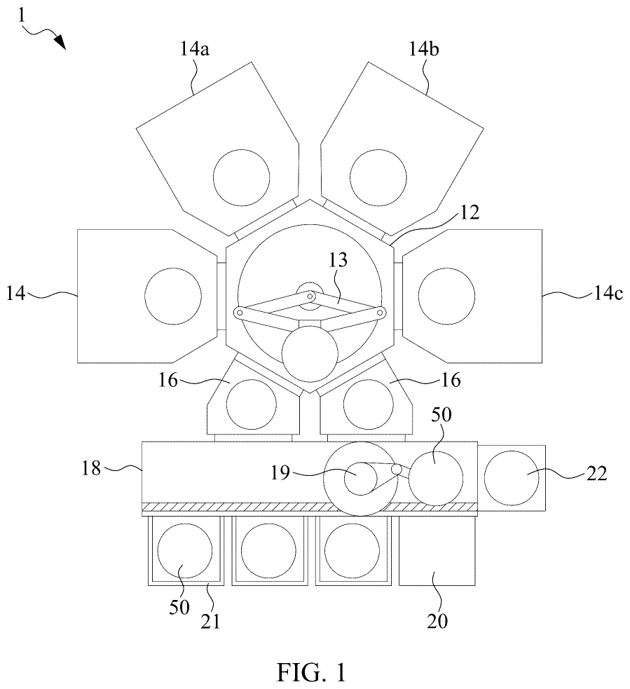

Referring to FIG. 1, in some embodiments, a semiconductor substrate processing system 10 is configured to process a substrate 50. The substrate 50 may include one or more semiconductor, conductor, and/or insulator layers. The semiconductor layers may include an elementary semiconductor such as silicon or germanium with a crystalline, polycrystalline, amorphous, and/or another suitable structure; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; any other suitable material; and/or combinations thereof. In some embodiments, combinations of semiconductors may take the form of a mixture or gradient such as a substrate in which the ratio of Si and Ge vary across locations. In some embodiments, the substrate 50 may include layered semiconductors. Examples include the layering of a semiconductor layer on an insulator such as that used to produce a silicon-on-insulator (SOI) substrate, a silicon-on-sapphire substrate, or a silicon-germanium-on-insulator substrate, or the layering of a semiconductor on glass to produce a thin film transistor (TFT).

As shown in FIG. 1, the semiconductor substrate processing system 10 is a cluster tool, which includes a central transfer chamber 12 with a delivery assembly 13 (e.g., a multi-axis robot manipulator), one or more process modules 14, 14a, 14b and 14c, one or more load lock chambers 16, an equipment front end module (EFEM) 18 with a delivery assembly 19 (e.g., a multi-axis robot manipulator), one or more load ports 20, and an orientation chamber 22. The central transfer chamber 12 connects to the process modules 14 and to the load lock chambers 16. This configuration allows the delivery assembly 13 to transfer the substrate 50 between the process modules 14 and the load lock chambers 16. It should be understood that the elements of the semiconductor substrate processing system 10 can be added or omitted in different embodiments, and the invention should not be limited by the embodiments.

The process modules 14 may be configured to perform various manufacturing procedures on the substrate 50. Substrate manufacturing procedures may include deposition processes such as physical vapor deposition (PVD), chemical vapor deposition (CVD), plasma-enhanced chemical vapor deposition (PECVD), electrochemical deposition (ECD), molecular beam epitaxy (MBE), atomic layer deposition (ALD) and/or other deposition processes; etching processes including wet and dry etching and ion beam milling; lithographic exposure; ion implantation; thermal processes such as annealing and/or thermal oxidation; cleaning processes such as rinsing and/or plasma ashing; chemical mechanical polishing or chemical mechanical planarizing (collectively “CMP”) processes; testing; any procedure involved in the processing of the substrate 50; and/or any combination of procedures. In some embodiments, each process module 14 is used to perform a specific manufacturing procedure on the substrate 50. In various embodiments, the substrate 50 may be processed by one or more process modules 14 before being sent out of the semiconductor substrate processing system 10.

In some embodiments, the area of the semiconductor substrate processing system 10 defined by the central transfer chamber 12 and the process modules 14 is sealed. Atmospheric controls, including filtering, provide an environment with extremely low levels of particulates and airborne molecular contamination (AMC), both of which may damage the substrate 50. By creating a microenvironment within the semiconductor substrate processing system 10, the process modules 14 can be operated in a cleaner environment than the surrounding facilities. This allows tighter control of contaminants during substrate processing at reduced cost. Although not shown, the process modules 14 and the central transfer chamber 12 may operate in a vacuum by using a vacuum system during substrate processing.

The load lock chambers 16 may preserve the atmosphere within the central transfer chamber 12 and process modules 14 by separating them from the EFEM 18. As shown in FIG. 1, each load lock chamber 16 includes two doors, a first door connecting to the central transfer chamber 12 and a second door connecting to the EFEM 18. The substrate 50 is inserted into a load lock chamber 16 and both doors are sealed. The load lock chamber 16 is capable of creating an atmosphere compatible with the EFEM 18 or the central transfer chamber 12 depending on where the loaded substrate 50 is scheduled to be next. This may require altering the gas content of the load lock chamber 16 by such mechanisms as adding purified gases (or inert gases) or creating a vacuum, along with other suitable means for adjusting the load lock chamber atmosphere. When the correct atmosphere has been reached, the corresponding door may be opened, and the substrate 50 can be accessed. In some embodiments, a load lock chamber 16 may be configured to handle the unprocessed substrate 50 only, and another load lock chamber 16 may be configured to handle the processed substrate 50.

The EFEM 18 may provide a closed environment in which to transfer the substrate 50 into and out of the semiconductor substrate processing system 10. The EFEM 18 contains the delivery assembly 19 which performs the physical transfer of the substrate 50. In some embodiments, a gas handling system (not shown) may also be configured to generate a gas interface between the EFEM 18 and the load ports 20 to restrict the flow of air between the transport carriers 21 docked at the load ports 20 and the EFEM 18 and reduce cross-contamination.

The substrate 50 is loaded into and out of the semiconductor substrate processing system 10 through the load ports 20. In some embodiments, the substrate 50 arrives at a load port 20 contained in a transport carrier 21 such as a front-opening unified pod (FOUP), a front-opening shipping box (FOSB), a standard mechanical interface (SMIF) pod, and/or another suitable container. The transport carrier 21 is a magazine for holding one or more substrates W and for transporting substrates W between different manufacturing tools or working stations. In some embodiments, the transport carrier 21 may have features such as coupling locations and electronic tags to facilitate use with an automated materials handling system. The transport carrier 21 is sealed in order to provide a microenvironment for the substrate 50 contained within and to protect the substrate 50 and the semiconductor substrate processing system 10 against contamination. To prevent loss of the controlled atmosphere, the transport carrier 21 may have a door specially designed such that the transport carrier 21 remains sealed until it is docked with the load port 20. After being processed by one or more process modules 14, the substrate 50 may be transferred into another transport carrier 21 for the processed substrates W, which will be transported to the next processing system or inspection station.

The orientation chamber 22 may provide the function of orienting the substrate 50 prior to the subsequent manufacturing procedure(s). For example, in some embodiments shown in FIG. 1, the orientation chamber 22 connects to the EFEM 18. After the loaded substrate 50 is properly oriented in the orientation chamber 22 (through an orientation processing, which will be further described later), it can be transferred by the delivery assembly 19 of the EFEM 18 to a load lock chamber 16, and then be transferred by the delivery assembly 13 of the central transfer chamber 12 to one or more process modules 14 for the manufacturing procedures.

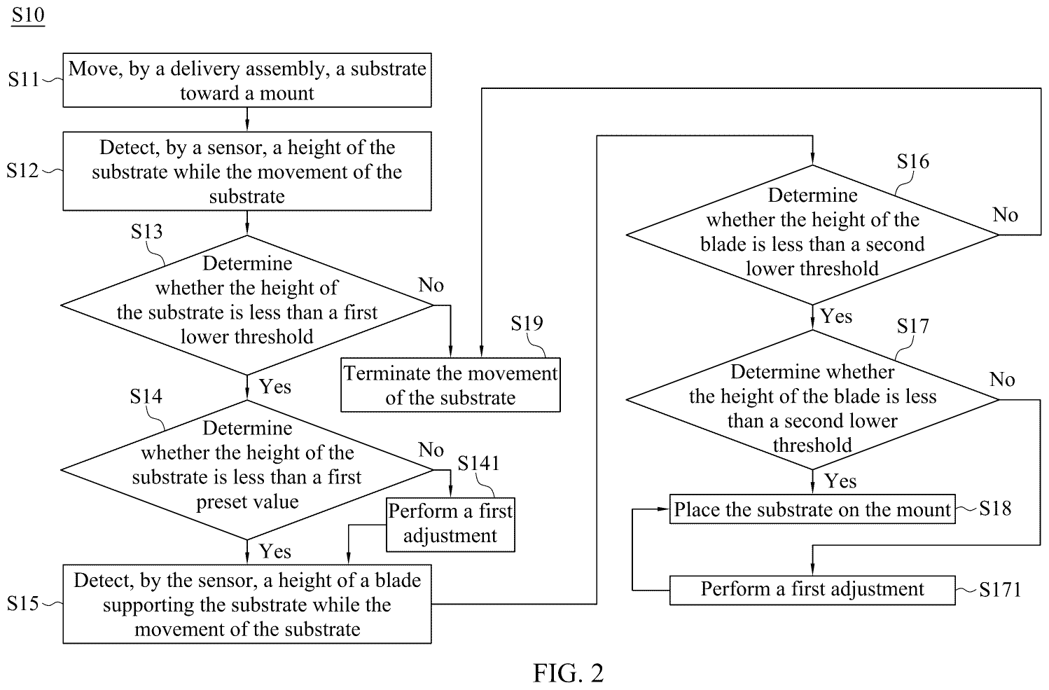

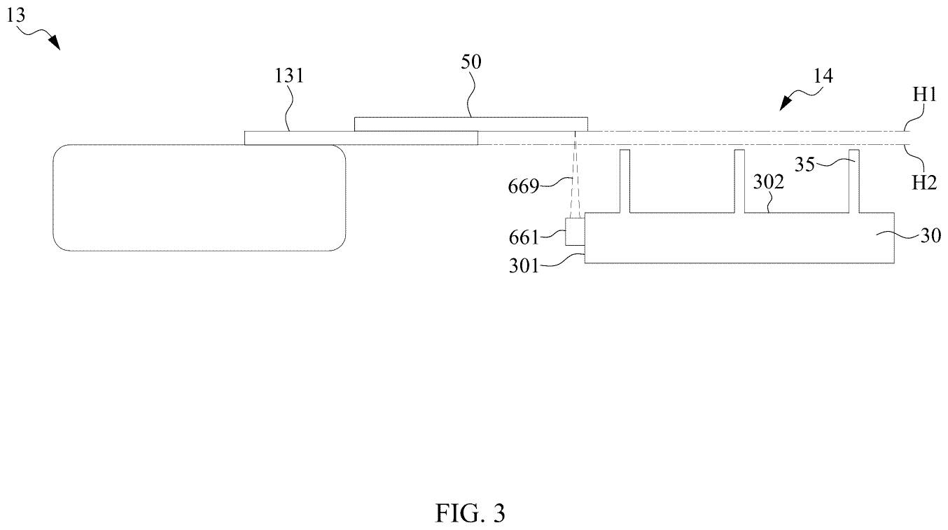

FIG. 2 is a flow chart illustrating a method S20 for delivering wafer substrate, in accordance with various aspects of one or more embodiments of the present disclosure. For illustration, the flow chart will be described along with the drawings shown in FIGS. 3-8. Some of the described stages can be replaced or eliminated in different embodiments.

The method S10 includes operation S11, in which the substrate 50 is moved toward a mount 30 using the delivery assembly 13. Referring to FIG. 3, in accordance with some embodiments, the substrate 50 is moved by the delivery assembly 13 to the mount 30 positioned in the process module 14.

In some embodiments, mount 30 is used for supporting the substrate 50 during a manufacturing process executed in the process module 14. The mount 30 may be a wafer chuck and includes a number of supporting pins 35 moveable relative to a top surface 302 of the mount 30. The supporting pins 35 are moved upward to protrude from the top surface 302 when the substrate 50 is loaded or unloaded from the mount 30. After the substrate 50 is placed on or removed from the supporting pins 35, they are moved downward so that the substrate 50 is placed on the top surface 302 of the mount 30.

In some embodiments, the substrate 50 is delivered into the process module 14 by the delivery assembly 13. The delivery assembly 13 may include a blade 131 for supporting the substrate 50. When the substrate 50 is positioned on the blade 131, an edge 51 of the substrate 50 extends beyond an end 133 of the blade 131 of the robot. The end 133 is the front end in the direction of the blade's movement during the transportation of the wafer to the mount 30. Under normal conditions, during the delivery movement of the wafer 50, the wafer 50 is maintained at a height H1 (first preset value), and the bottom surface 132 of the blade 131 is kept at a height H2 (second preset value). This normal condition presents that the substrate 50 does not collide with any part of the process module 14, and the substrate 50 can be stably placed on the supporting pins 35.

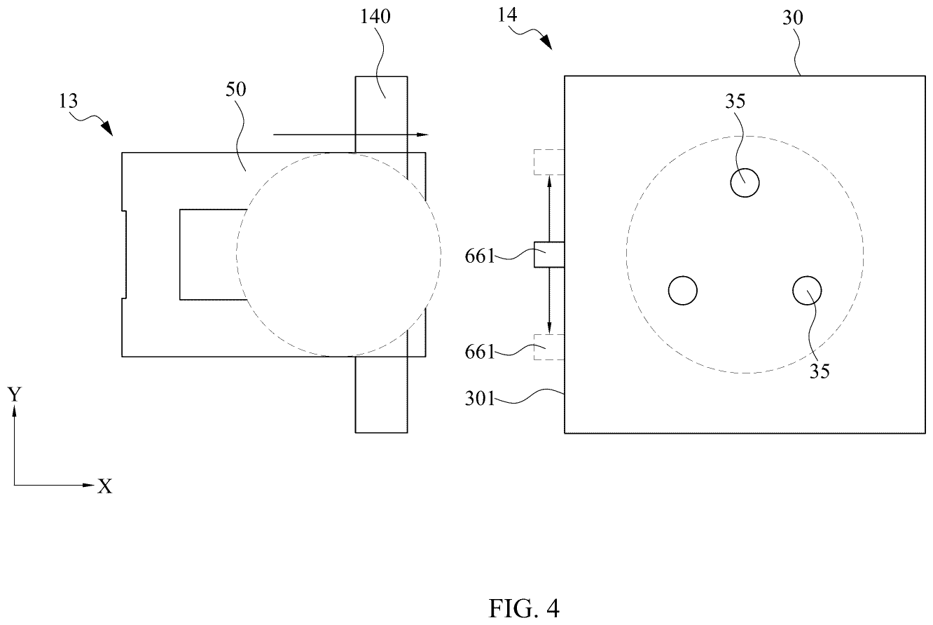

Referring to FIG. 4, in some embodiments, the substrate 50 is delivered by the delivery assembly 13 through an opening 140 in the process module 14 before approaching the mount 30. This opening 140 connects the interior of the process module 14 to the exterior, and it may be closed during the manufacturing process. The mount 30 has a side wall 301 which is a part of the mount that is closest to the opening 140. A sensor 661 is positioned on the side wall 301. This sensor 661 may be mounted on a rail (not shown in the figures), allowing it to move back and forth along the side wall 301. The sensor 661 may be a laser telemeter, comprising a laser transmitter for emitting laser beams 669 and a transducer for receiving the reflected laser beams. The sensor 661 is configured to detect a distance to an object based on the receive laser beam and determine a height of the object based on the detect distance. However, the embodiments of the present disclosure are not limited to this configuration. In an alternative embodiment, the sensor may include an image camera and an image analysis module. In this case, the image analysis module would analyze the captured image of an object to determine its distance.

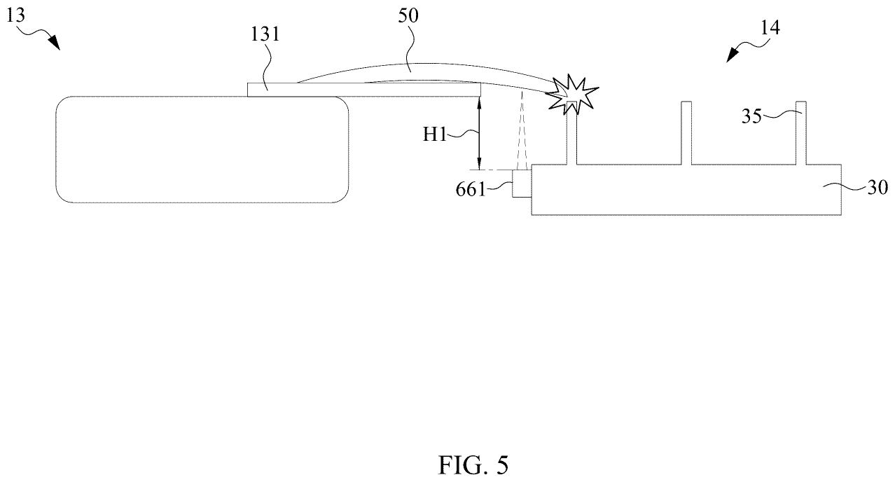

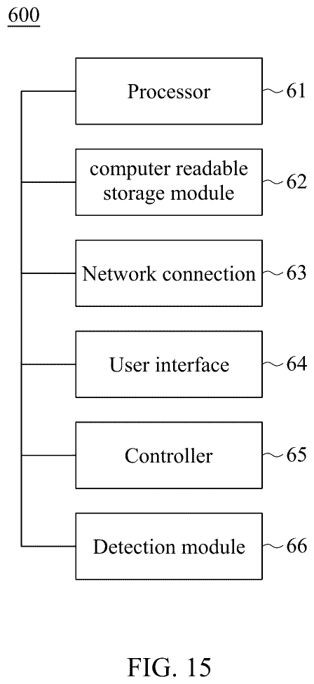

The method S10 also includes operation S12, in which a height of the substrate 50 is detected, by the sensor 661, while the movement of the substrate 50. In some embodiments, the sensor 661 begins emitting laser beams before the substrate 50 is moved by the delivery assembly 13. As a result, as soon as the edge 51 of the substrate 50, which is the leading edge in the direction of the wafer's movement, reaches above the sensor 661, the height of the edge 51 is detected immediately. The measurement result produced by the sensor 661 then be transmitted to a processor (FIG. 15) for further processing. When wafer warpage occurs, as shown in FIG. 5, the edge of the substrate 50 exhibits the highest or lowest height compared to the central portion of the substrate 50. Therefore, detecting the edge 51 of the substrate 50 facilitates the detection process for preventing wafer collisions.

In some embodiments, the sensor 661 moves back and forth in a direction perpendicular to the moving direction of the substrate 50, continuously detecting the height of the substrate 50 during its movement. For example, as shown in FIG. 4, the substrate 50 is moved along the X-axis direction, while the sensor 661 moves back and forth along the Y-axis direction. The sensor 661 scans the height of the substrate 50 throughout the entire transportation period. With such an arrangement, a topographic map of the substrate 50 can be produced before it is delivered to the mount 30.

The method S10 also includes operation S13, in which it is determined whether the height of the substrate 50 is less than a first lower threshold. The first lower threshold may indicate a height of the substrate 50 at which it may collide with the supporting pins 35, as shown in FIG. 5. The first lower threshold may be set as the distance between the tip of one of the supporting pins 35 and the top surface of the sensor 661. If the measurement result produced by the sensor 661 indicates that the height of the edge 51 of the substrate 50 is lower than the first lower threshold, the delivery assembly 13 is controlled to stop the movement of the substrate 50 (operation S19) before it collides with the supporting pins 35. Operation S19 may further include removing the substrate 50 from the process module 14. If the measurement result shows the height exceeds the first lower threshold, the method S10 continues to operation S14.

In operation S14, it is determined whether the height of the substrate 50 is less than a first preset value. The first preset value may be the first height H1 as shown in FIG. 3. The first height H1 may be set according to historical data of the average height of the substrate 50 detected during preceding processes in which no collision occurred. If the measurement result shows the height of the substrate 50 is less than the first preset value but greater than the first lower threshold, the method S10 continues to S141, in which a first adjustment is performed. In the first adjustment, the height of the blade 131 (or the substrate 50) is raised so that the wafer is moved back to the first preset value.

If the measurement result shows the height meets or exceeds the first preset value, the movement of the substrate 50 continues to operation S15 without any adjustment being needed, and the method S10 continues to operation S15 unless the measurement result shows that the height of the substrate 50 over a first upper threshold. The first upper threshold may indicate that the height could cause the substrate 50 to collide with other components positioned over mount 30, or that the substrate 50 may not be properly placed on supporting pins 35 due to its excessive height.

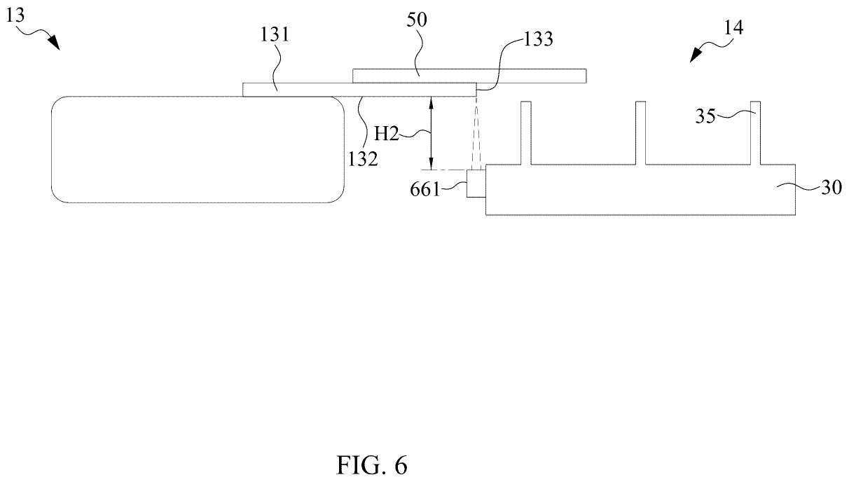

In operation S15, as shown in FIG. 6, the height of the blade 131 which supports the substrate 50 is detected while the substrate 50 is in motion. In some embodiments, the height of the end 133 of the blade 131 is detected. Since the end 133 is the leading edge in the direction of the blade's movement during the transportation of the wafer to the mount 30, detecting the height of the end 133 enables the system to respond early for the subsequent operations S16 and S17.

In operation S16, it is dhether the height of the blade 131 is less than a second lower threshold. The second lower threshold may indicate a height of the blade 131 at which it may collide with the supporting pins 35, as shown in FIG. 5. The second lower threshold may be set as the distance between the tip of one of the supporting pins 35 and the top surface of the sensor 661. If the measurement result produced by the sensor 661 indicates that the height of the end 133 of the blade 131 is lower than the second lower threshold, the delivery assembly 13 is controlled to stop the movement of the substrate 50 (operation S19) before it collides with the supporting pins 35. If the measurement result shows the height exceeds the second lower threshold, the method S10 continues to operation S17.

In operation S17, it is determined whether the height of the blade 131 is less than a second preset value. The second preset value may be the second height H2 as shown in FIG. 3. The second height H2 may be set according to historical data of the average height of the blade 131 detected during preceding processes in which no collision occurred. If the measurement result shows the height of the blade 131 is less than the second preset value but greater than the second lower threshold, the method S10 continues to operation S171, in which a second adjustment is performed. In the second adjustment, the height of the blade 131 (or the substrate 50) is raised so that the blade 131 is moved back to the second preset value. This procedure helps prevent collisions arising when the wafer is warped upward, leading to no height adjustment being made in operation S14. By continuously monitoring the height of the blade and implementing any required adjustments, the risk of collisions is effectively mitigated. If the measurement result shows the height meets or exceeds the second preset value, the movement of the substrate 50 continues without any adjustment being needed, and the method S10 continues to operation S18.

If the measurement result shows the height meets or exceeds the first preset value, the movement of the substrate 50 continues to operation S15 without any adjustment being needed, and the method S10 continues to operation S18 unless the measurement result shows that the height of the blade 131 over a second upper threshold. The second upper threshold may indicate that the height could cause the blade 131 or the substrate 50 to collide with other components positioned over mount 30, or that the substrate 50 may not be properly placed on supporting pins 35 due to its excessive height.

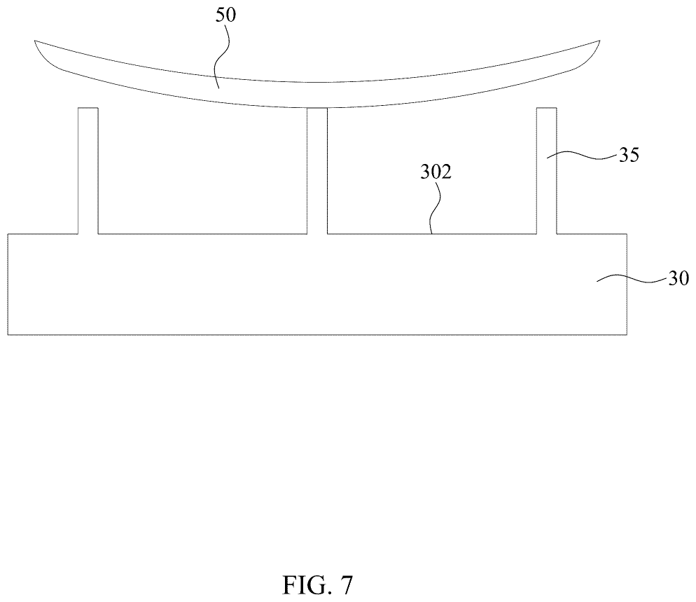

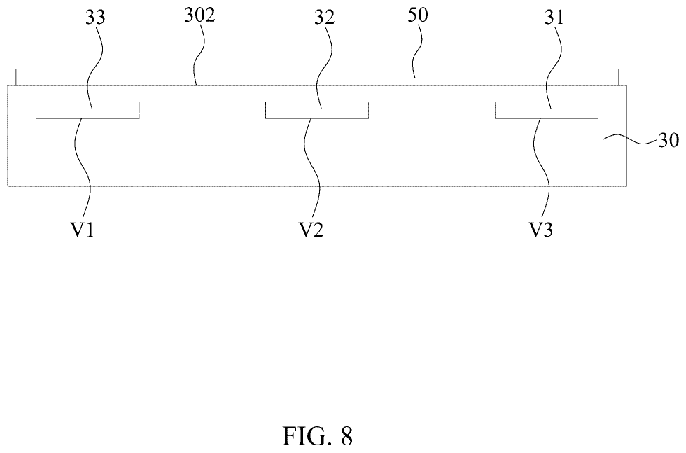

In operation S18, as shown in FIG. 7, the substrate 50 is placed on the supporting pins 35. Once the substrate 50 is positioned, the blade 131 is removed, and the supporting pins 35 are lowered down. In some embodiments, as shown in FIG. 8, the substrate 50 is held on the mount 30 by the fastening force produced by electrodes 31, 32, and 33 located underneath the top surface 302 of the mount 30. In some embodiments, the fastening force produced by these electrodes 31, 32, and 33 is dynamically controlled according to the topographic map of the substrate 50, which is produced by the height measurement. For example, in the case where the wafer exhibits upward warping, as shown in FIG. 7, the electrodes 31 and 33, which are located below the peripheral region of the substrate 50, may apply a greater fastening force to the substrate 50 than the electrode 32, which is located below the central region of the wafer. Arranged in this manner, the flatness of the wafer can be properly adjusted, which helps increase the quality of the substrate. For instance, during film deposition processes, a flatter wafer surface enables more uniform film formation, leading to improved product quality. Operations S11-18 may be executed each time where a new substrate 50 is moved to the mount 30 by the delivery assembly 13.

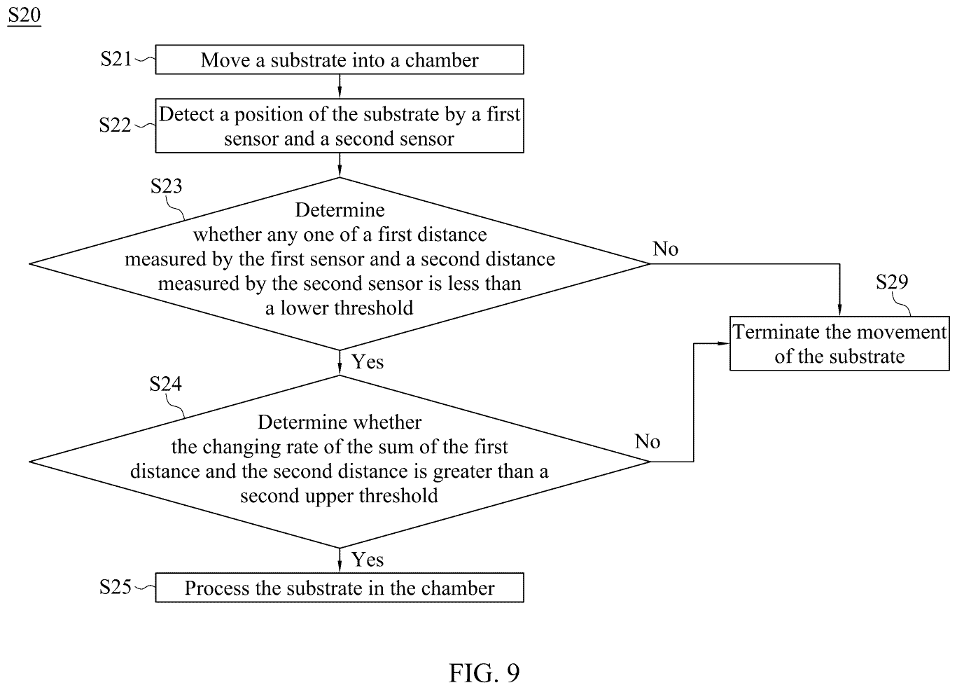

FIG. 9 is a flow chart illustrating a method S20 for performing a CMP process, in accordance with various aspects of one or more embodiments of the present disclosure. For illustration, the flow chart will be described along with the drawings shown in FIGS. 1, 2 and 8-10. Some of the described stages can be replaced or eliminated in different embodiments.

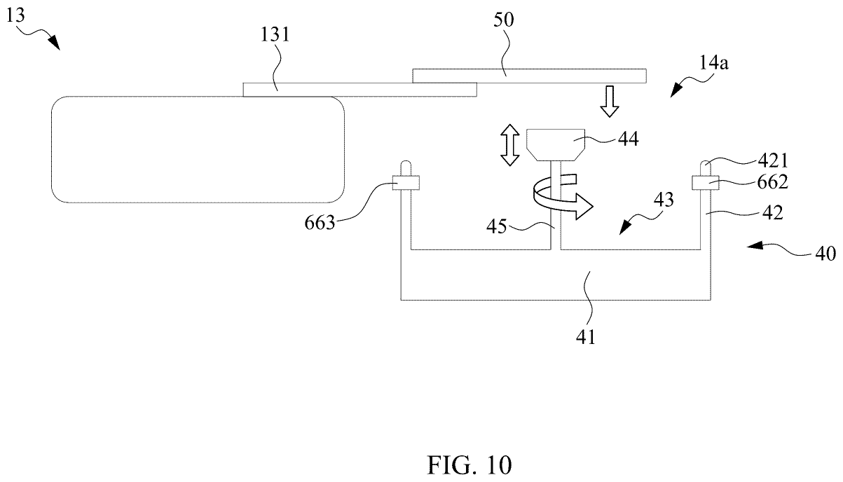

The method S20 includes operation S21, in which the substrate 50 is moved into a chamber 40. Referring to FIG. 10, in accordance with some embodiments, the substrate 50 is moved by the delivery assembly 13 into a process module 14a, in which the chamber 40 is located. The chamber 40 may include a side wall 42 extends up ward to define an interior 43 of the chamber 40. A mount 44 is positioned in the chamber 40 and connected to a rotation shaft 45. The mount 44 is moveable relative to a bottom 41 of the chamber 40 by the rotation shaft 45. In operation, the rotation shaft 45 is moved away from the bottom 41 when the substrate 50 is loaded from the delivery assembly 13 to the mount 44. After the substrate 50 is placed on the supporting pins 35, the rotation shaft 45 is moved downward so that the substrate 50 is placed within the interior 43 of the chamber 40.

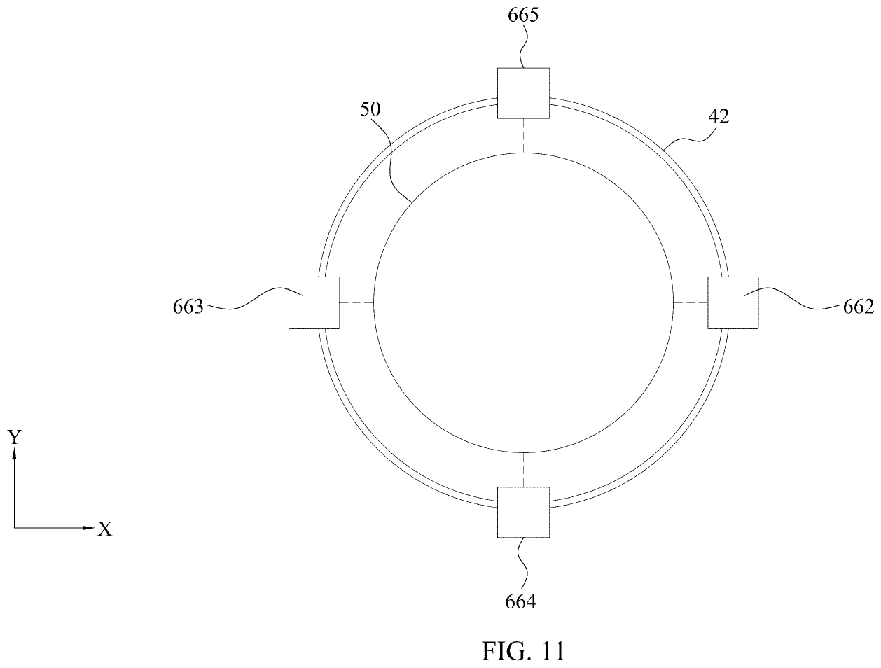

At least two sensors are positioned on the side wall 42 of the chamber 40. For example, as shown in FIG. 10, two sensors 662 and 663 are positioned at a top end 421 of the side wall 42. The two sensors 662 and 663 are positioned opposite to each other. In some other embodiments, as shown in FIG. 11, four sensors 662, 663, 664 and 665 are positioned at the side wall 42. The two sensors 662 and 663 are positioned opposite to each other in an X-axis direction, and the two sensors 664 and 665 are positioned opposite to each other in a Y-axis direction. The X-axis direction is perpendicular to the Y-axis direction. The sensor 662, 663, 664 and 665 may each include a laser telemeter, an image camera, or something that can be used to detect a distance of an object.

The method S20 also includes operation S22, in which the position of the substrate 50 is detected by the sensors 662, 663, 664, and 665 while the substrate 50 is in motion. In some embodiments, the sensors 662, 663, 664, and 665 begin emitting laser beams before the substrate 50 is moved by the mount 44. As a result, as soon as the bottom surface of the substrate 50, which is the leading surface in the direction of the substrate's movement, rises above the top end 421 of the chamber 40, the position of the substrate 50 is detected immediately. The measurement results produced by the sensors 662, 663, 664, and 665 are then transmitted to a processor 61 (FIG. 15) for further processing.

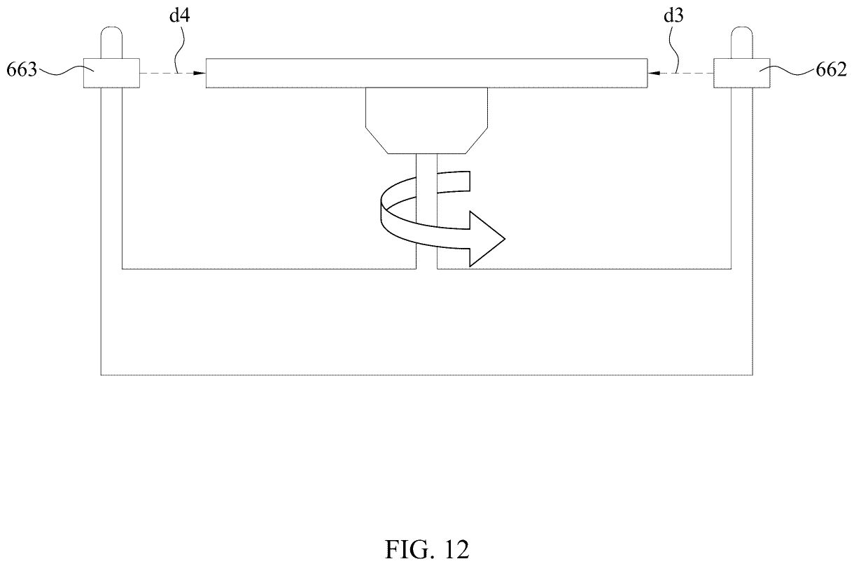

The method S20 also includes operation S23, in which it is determined whether any distance measured by the sensors 662, 663, 664, and 665 is less than a lower threshold. For example, as shown in FIG. 12, the sensor 662 detects a first distance d3 between an edge 51 of the substrate 50 and itself, while the sensor 663 detects a second distance d4 between the edge 51 of the substrate 50 and itself. If the measurement result produced by any one of the sensors 662 and 663 indicates that the distance between the edge 51 of the substrate 50 and the corresponding sensor is lower than the lower threshold, the mount 44 is controlled to stop the movement of the substrate 50 (operation S29) before it collides with the side wall 42 or any other component in the chamber 40.

After operation S29, the method S20 may further include adjusting the position of the substrate 50 according to the measurement results produced by the sensors 662, 663, 664, and 665. For example, the substrate 50 may be placed back onto the delivery assembly 13 from the mount 44. The delivery assembly 13 moves the substrate 50 in the X-axis direction to compensate for the position error based on the measurement results from the sensors 662 and 663. Additionally, the delivery assembly 13 moves the substrate 50 in the Y-axis direction to compensate for the position error based on the measurement results from the sensors 664 and 665. After the adjustment, the substrate 50 may be loaded onto the mount 44 again for further processing.

If the measurement results show that the heights exceed the lower threshold, the method S20 continues to operation S24. The lower threshold represents a distance at which a collision may occur or indicates that the substrate 50 is not positioned at the center of the chamber 40.

Since measurement errors (e.g., the sensor is not calibrated correctly) may occur, in some embodiments, operation S23 may further include determining whether the sum of the first distance measured by the first sensor and the second distance measured by the second sensor is equal to or greater than a specific value. The specific value is the sum of the distances between the substrate 50 and the two sensors positioned opposite to each other when the substrate 50 is correctly placed. If the sum of the two distances is less than the specific value, it means one of the sensors is malfunctioning. In this case, the method S20 continues to operation S24.

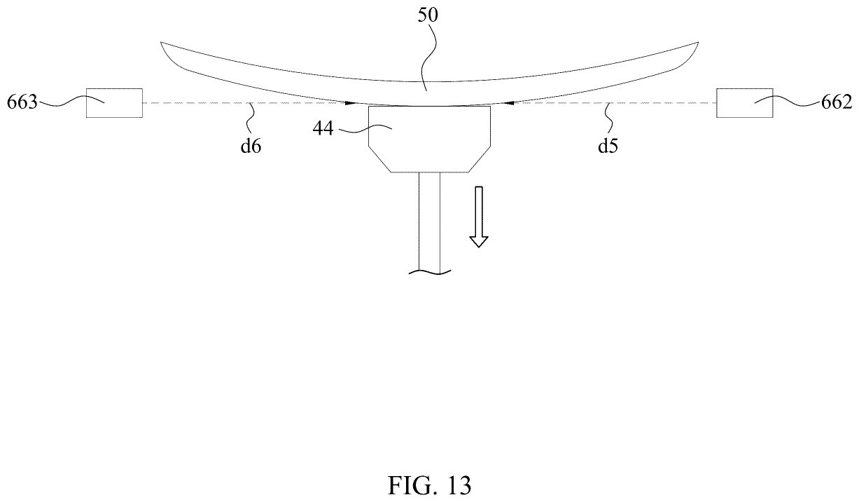

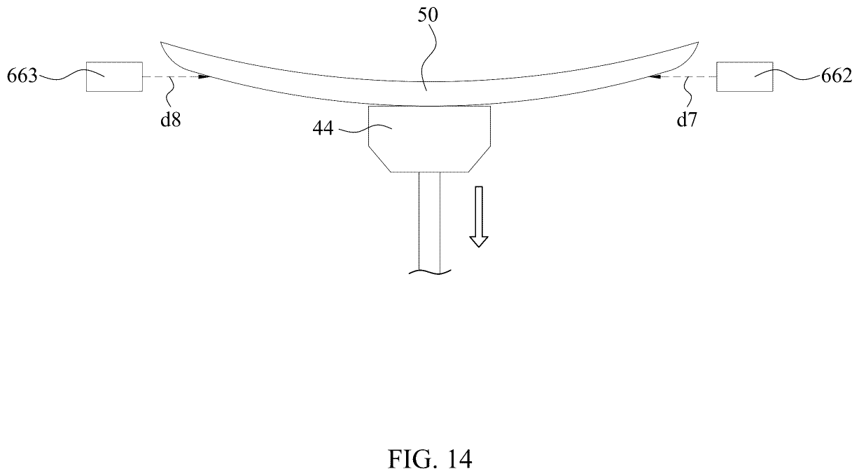

In operation S24, it is determined whether the changing rate of the first distance and the second distance is greater than a second upper threshold. In some embodiments, the warpage curve of the wafer is monitored based on the measurement data from sensors 662, 663, 664, and 665. FIGS. 13 and 14 depict two stages of the distance measurements taken by sensors 662 and 663 at the first time point (FIG. 13) and the second time point (FIG. 14) during the wafer's descent. At the first time point, sensor 662 records distance d5, while sensor 663 records distance d6. At the second time point, sensor 662 measures distance d7, and sensor 663 measures distance d8. By analyzing the rate of change in either the distance d5 and the distance d7 or the distance d6 and the distance d8, the curvature profile of the warped wafer can be calculated. If the rate of change in the distance measured by either sensor 662 or 663 is greater than the second upper threshold, the movement of the substrate 50 is stopped (operation S29) to prevent further processing that could potentially lead to defects or damage. The second upper threshold may correspond to an upper limit of acceptable wafer curvature for the substrate 50.

The method S20 further includes operation S25. After the substrate 50 passing through upper opening of the chamber 40, where the sensors 662, 663, 664, and 665 are located, the substrate 50 is positioned in the interior 43 of the chamber 40. The substrate 50 is then be processed in the chamber 40. In some embodiments, a coating process or a cleaning process is performed by dispensing chemical or cleaning liquid over the substrate 50, and the mount 30 may rotate the substrate 50 during the process. Operations S21-25 may be executed each time where a new substrate 50 is moved to the chamber 40 by the mount 44.

It will be appreciated that the substrate delivery method disclosed in the embodiments of the present disclosure can be applied to the movement of substrates 50 between any positions within the semiconductor substrate processing system 10 with the use of the delivery assembly 13 or the delivery assembly 19. In addition, the substrate delivery method can be applied to the movement of substrates 50 in other processing tool in a semiconductor FAB, and would not be limited to the embodiments disclosed in the present disclosure.

FIG. 15 is a block diagram of various functional modules of a semiconductor substrate processing system 10, in accordance with some embodiments. The semiconductor substrate processing system 10 may a processor 61. In further embodiments, the processor 61 may be implemented as one or more processors. The processor 61 may be operatively connected to a computer readable storage module 62 (e.g., a memory and/or data store), a network connection module 63, a user interface module 64, a controller module 65, and a detection module 66.

In some embodiments, the computer readable storage module 62 may include robot delivery operation logic that may configure the processor 61 to perform the various processes discussed herein. The computer readable storage module 62 may also store data, such as sensor data characterizing wafer defects, control instructions for an delivery assembly and/or robotic arm to orient a wafer in accordance with an orientation fiducial and/or to facilitate defect sensor data collection, identifiers for a wafer, identifiers for a delivery assembly, identifiers for a semiconductor workpiece fabrication process, and any other parameter or information that may be utilized to perform the various processes discussed herein.

The network connection module 63 may facilitate a network connection of the semiconductor substrate processing system 10 with various devices and/or components of the semiconductor substrate processing system 10 that may communicate (e.g., send signals, messages, instructions, or data) within or external to the semiconductor substrate processing system 10. In certain embodiments, the network connection module 63 may facilitate a physical connection, such as a line or a bus. In other embodiments, the network connection module 63 may facilitate a wireless connection, such as over a wireless local area network (WLAN) by using a transmitter, receiver, and/or transceiver. For example, the network connection module 63 may facilitate a wireless or wired connection with the processor 61 and the computer readable storage module 62.

The semiconductor substrate processing system 10 may also include the user interface module 64. The user interface may include any type of interface for input and/or output to an operator of the semiconductor substrate processing system 10, including, but not limited to, a monitor, a laptop computer, a tablet, or a mobile device, etc.

The semiconductor substrate processing system 10 may include a controller module 65. The controller module 65 may be configured to control various physical apparatuses that control movement or functionality for a robotic arm, defect sensor, processing chamber, or any other controllable aspect of the system. For example, the controller module 65 may be configured to control movement or functionality for at least one of a door of the chamber, a rotational motor that rotates the delivery assembly around an axis of rotation, and the like. For example, the controller module 65 may control a motor or actuator. The controller may be controlled by the processor and may carry out the various aspects of the various processes discussed herein.

The detection module 66 may represent a defect sensor and/or orientation sensor configured to collect sensor data. As discussed above, in certain embodiments an orientation sensor may include an emitter and detector pair in which an emitter emits detectible radiation (e.g., a laser beam) which is detected by a detector. For example, the radiation may be detectible only at a location along the wafer's bezel where there is an orientation fiducial, such as a notch or a flat. In particular embodiments, a center sensor may be utilized to detect whether a wafer is centered on a pedestal, such as at an axis of rotation. For example, the center sensor may be configured to detect a location of a center fiducial (e.g., a fiducial at a center of a wafer) or may be determined to determine distances between the center of rotation to the periphery of the wafer along a linear path so that a wafer center point offset may be calculated by geometric analysis of the measurements.

Embodiments of present disclosure providing methods and systems for handling wafer substrates in semiconductor manufacturing. A delivery assembly moves the substrate towards a mount, while sensors detect the substrate's height or position. If the detected height/position indicates a potential collision risk, the substrate movement is terminated. If the height exceeds a threshold but is below a preset value, adjustments are made to the delivery assembly's blade position for proper alignment. The method and system of the embodiments are also used to real time measurement result to create a wafer profile for detecting wafer warpage. As a result, warpage can be detected early, thereby reducing manufacturing costs, material losses, and enhancing production efficiency in semiconductor fabrication processes.

According to some embodiments of present disclosure, a method of a wafer substrate in semiconductor manufacturing is provided. The method includes moving, by a delivery assembly, the substrate toward a mount. The delivery assembly comprising a blade, and the substrate is positioned on the blade. The method also includes detecting, by a sensor, a height of the substrate relative to the mount while the movement of the substrate. When the height of the substrate is less than a first lower threshold, the method includes terminating the movement of the substrate. When the height of the substrate is greater than the first threshold but less than a first preset value, the method includes keep moving the substrate and performing a first adjustment to adjust the position of the blade according to the height of the substrate.

According to some embodiments of present disclosure, a method of a wafer substrate in semiconductor manufacturing is provided. The method includes moving a substrate into a chamber. The method also includes detecting, by a first sensor and a second sensor, a position of the substrate, wherein the chamber comprises a side wall, and the first and the second sensors are positioned at a top of the side wall. In addition, the method includes when any one of a first distance measured by the first sensor and a second distance measured by the second sensor is less than a lower threshold, terminating the movement of the substrate.

According to other embodiments of present disclosure, a system for processing a wafer substrate is provided. The system includes a delivery assembly comprising a blade configured to hold a substrate. The system also includes a mount configured to hold the substrate. In addition, the system includes a sensor positioned on the mount. Furthermore, the system includes a controller. The controller is used to control the delivery assembly to move the substrate on the delivery assembly toward the mount. The controller is also used to terminate the movement of the delivery assembly when a measurement result produced by the sensor indicating that the height of the substrate is less than a lower threshold. In addition, the controller is used to adjust the position of the blade according to the height of the substrate when the measurement result produced by the sensor indicating the height of the substrate is greater than the threshold but less than a preset value.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
moving, by a delivery assembly, a substrate toward a mount, wherein the delivery assembly comprising a blade, and the substrate is positioned on the blade;
detecting, by a sensor, a height of the substrate relative to the mount while the movement of the substrate;
when the height of the substrate is less than a first lower threshold, terminating the movement of the substrate; and
when the height of the substrate is greater than the first threshold but less than a first preset value, keep moving the substrate and performing a first adjustment to adjust the position of the blade according to the height of the substrate.

2. The method of claim 1, wherein the substrate is moved in a horizontal direction, and an edge of the substrate is closer to the mount than an end of the bade, and the method further comprises:
detecting, by the sensor, a height of the bade relative to the mount after the edge of substrate passing over through the sensor; and
when the height of the blade is less than a second lower threshold, terminating the movement of the substrate.

3. The method of claim 2, wherein the method further comprises:
when the height of the blade is greater than the second threshold but less than a second preset value keeping the movement of the substrate and performing a second adjustment to adjust the position of the blade.

4. The method of claim 1, wherein the sensor detects the height of the substrate by emitting a signal toward the edge of the substrate that is most closer to the mount.

5. The method of claim 1, wherein the method further comprises:
when the height of the substrate is greater than the first preset value keep moving the substrate without changing the position of the blade.

6. The method of claim 1, wherein the substrate is moved in an X-axis direction axis and the method further comprises moving the sensor back and forth in a Y-axis direction, and continuously detecting the height of the substrate.

7. The method of claim 1, further comprising establishing a topographic map of the substrate according the detected height.

8. The method of claim 7, further comprising adjusting a fastening force applied by the mount when the substrate is positioned on the mount according to the topographic map.

9. The method of claim 1, wherein the substrate is moved from an opening of a chamber toward a mount, and the sensor is positioned at a position of the mount that is most closer to the opening.

10. The method of claim 1, wherein the sensor emits a laser beam toward the substrate and determines the height of the substrate according to a reflection of the laser beam.

11. A method, comprising:
moving a substrate into a chamber;
detecting, by a first sensor and a second sensor, a position of the substrate, wherein the chamber comprises a side wall, and the first and the second sensors are positioned at a top of the side wall;
when any one of a first distance measured by the first sensor and a second distance measured by the second sensor is less than a lower threshold, terminating the movement of the substrate.

12. The method of claim 11, wherein the first and the second sensor are positioned opposite to each other in a horizontal direction.

13. The method of claim 12, wherein the sensor continuously detecting the position of the substrate while the movement of the substrate.

14. The method of claim 13, wherein when a changing rate of the sum of the first distance and the second distance is greater than a second upper threshold, terminating the movement of the substrate.

15. The method of claim 12, wherein the method further comprising detecting the position of the substrate by a third sensor and a fourth sensor which are positioned opposite to each other in the horizontal direction.

16. The method of claim 11, wherein the method further comprising adjusting the position of the substrate according to the first distance and the second distance after the movement of the substrate is terminated.

17. The method of claim 11, wherein the first sensor and the second sensor emit laser beams toward the substrate and determine the height of the substrate according to a reflection of the laser beams.

18. A system, comprising:
a delivery assembly, comprising a blade configured to hold a substrate;
a mount, configured to hold the substrate;
a sensor, positioned on the mount; and
a controller, configured to:
control the delivery assembly to move the substrate on the delivery assembly toward the mount;
terminate the movement of the delivery assembly when a measurement result produced by the sensor indicating that the height of the substrate is less than a lower threshold; and
adjust the position of the blade according to the height of the substrate when the measurement result produced by the sensor indicating the height of the substrate is greater than the threshold but less than a preset value.

19. The system of claim 18, further comprising a chamber having an opening, wherein the mount is positioned in the chamber, the delivery assembly moves the substrate into the chamber through the opening, wherein the sensor is positioned on a side surface of the mount that is most close to the opening.

20. The system of claim 18, wherein the sensor comprises a laser telemeter.
